(19) United States
(12) Patent Application Publication
(10) Pub. No.: US 2010/0139751 A1
(43) Pub. Date: Jun. 10, 2010

(54) PHOTOVOLTAIC DEVICE AND MANUFACTURING METHOD THEREOF

(75) Inventors: Takeyuki Sekimoto, Anpachi-gun (JP); Shigeo Yata, Kobe-shi (JP)

Correspondence Address: DITTHAVONG MORI & STEINER, P.C., 918 Prince Street, Alexandria, VA, 22314, US

(73) Assignee: SANYO ELECTRIC CO., LTD., Moriguchi-shi (JP)

(21) Appl. No.: 12/630,384

(22) Filed: Dec. 3, 2009

(30) Foreign Application Priority Data
Dec. 9, 2008 (JP) 2008-313005

(51) Int. Cl. H01L 31/00; H01L 31/108; H01L 31/18

(52) U.S. Cl. 136/255; 438/92; 257/E31.065

(57) ABSTRACT

A first solar battery unit and a second solar battery unit are stacked between a front-side electrode and a backside electrode and sandwiching an intermediate layer having conductivity, and a Schottky barrier is formed between the intermediate layer and an electrode connecting layer which connects the front-side electrode and the backside electrode.

### CROSS-REFERENCE TO RELATED APPLICATION

This application claims priority to Japanese Patent Application No. 2008-313005.

### BACKGROUND OF THE INVENTION

1. Field of the Invention

The present invention relates to a photovoltaic device and a manufacturing method thereof.

2. Description of the Related Art

A tandem-type photovoltaic device is known in which two solar battery units 10 and 12 (upper and lower solar battery units) are stacked with an intermediate layer 14 therebetween, as shown in FIG. 5. For the intermediate layer 14 sandwiched between the upper and lower solar battery units 10 and 12, one or more types of transparent conductive films are used. In addition, at a part of a backside electrode, a backside electrode 18 made of silver (Ag) which also functions as a backside reflective layer is formed, and the backside electrode 18 is connected to a front-side electrode 16 through a groove D formed through the stacked structure to the front-side electrode 16.

In such a structure, the intermediate layer 14 sandwiched between the upper and lower solar battery units 10 and 12 is partially in contact with the backside electrode 18 at the groove D.

When the intermediate layer 14 and the backside electrode 18 are in electrical contact with each other, leakage of current is caused at the point of contact, and a power generation characteristic of the photovoltaic device is reduced.

The present invention has been conceived in view of the above-described circumstances, and an advantage of the present invention is that a photovoltaic device and a manufacturing method thereof are provided in which reduction in characteristic due to contact between the intermediate layer and the backside electrode is inhibited.

### SUMMARY OF THE INVENTION

According to one aspect of the present invention, there is provided a photovoltaic device in which a first solar battery unit and a second solar batter unit are stacked between a first electrode and a second electrode and sandwiching an intermediate layer having conductivity, wherein a Schottky barrier is formed between the intermediate layer and a material which connects the first electrode and the second electrode.

According to another aspect of the present invention, there is provided a method of manufacturing a photovoltaic device in which a first solar battery unit and a second solar battery unit are stacked between a first electrode and a second electrode and sandwiching an intermediate layer having conductivity, the method comprising a first step in which a groove is formed through the first solar battery unit, the second solar battery unit, and the intermediate layer and reaching a front surface of the first electrode, and a second step in which a material which connects the first electrode and the second electrode through the groove and which forms a Schottky barrier with the intermediate layer is embedded.

### BRIEF DESCRIPTION OF THE DRAWINGS

An exemplary embodiment of the present invention will be described in detail based on the following figures, wherein:

FIG. 1 is a schematic cross sectional diagram showing a structure of a photovoltaic device according to a preferred embodiment of the present invention;

FIG. 2 is a diagram showing manufacturing steps of the photovoltaic device according to a preferred embodiment of the present invention;

FIG. 3 is a diagram for explaining a Schottky connection between an intermediate layer and an electrode connecting layer in a photovoltaic device according to a preferred embodiment of the present invention;

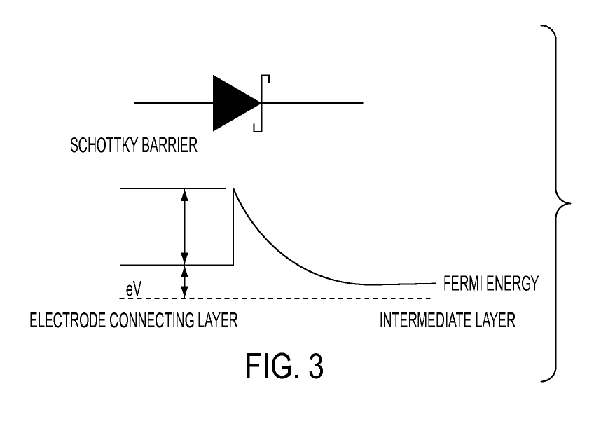

FIG. 4 is a diagram for explaining a relationship between a height of the Schottky barrier, between the intermediate layer and the electrode connecting layer, and current leakage in a photovoltaic device according to a preferred embodiment of the present invention: and

FIG. 5 is a schematic cross sectional diagram showing a structure of a photovoltaic device in related art.

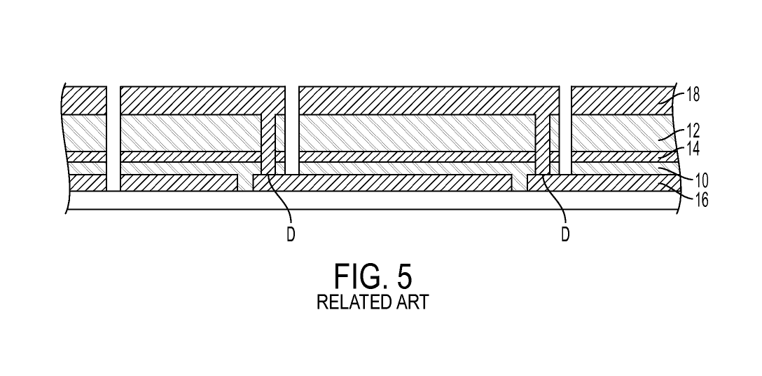

### DESCRIPTION OF THE PREFERRED EMBODIMENTS

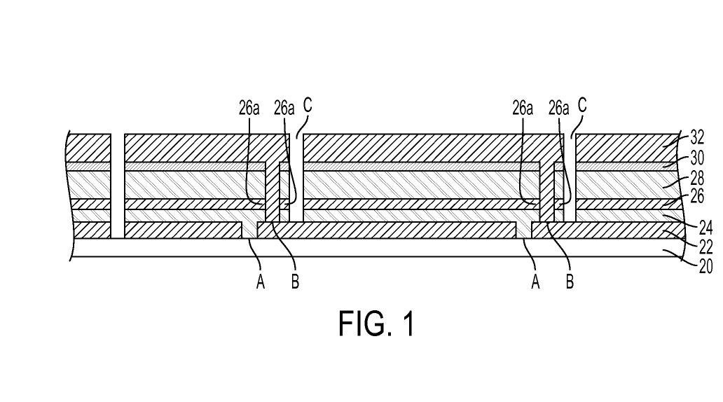

As shown in a cross sectional diagram of FIG. 1, a photovoltaic device 100 according to a preferred embodiment of the present invention comprises a substrate 20, a front-side electrode 22, a first solar battery unit 24, an intermediate layer 26, a second solar battery unit 28, a backside electrode 30, and an electrode connecting layer 32.

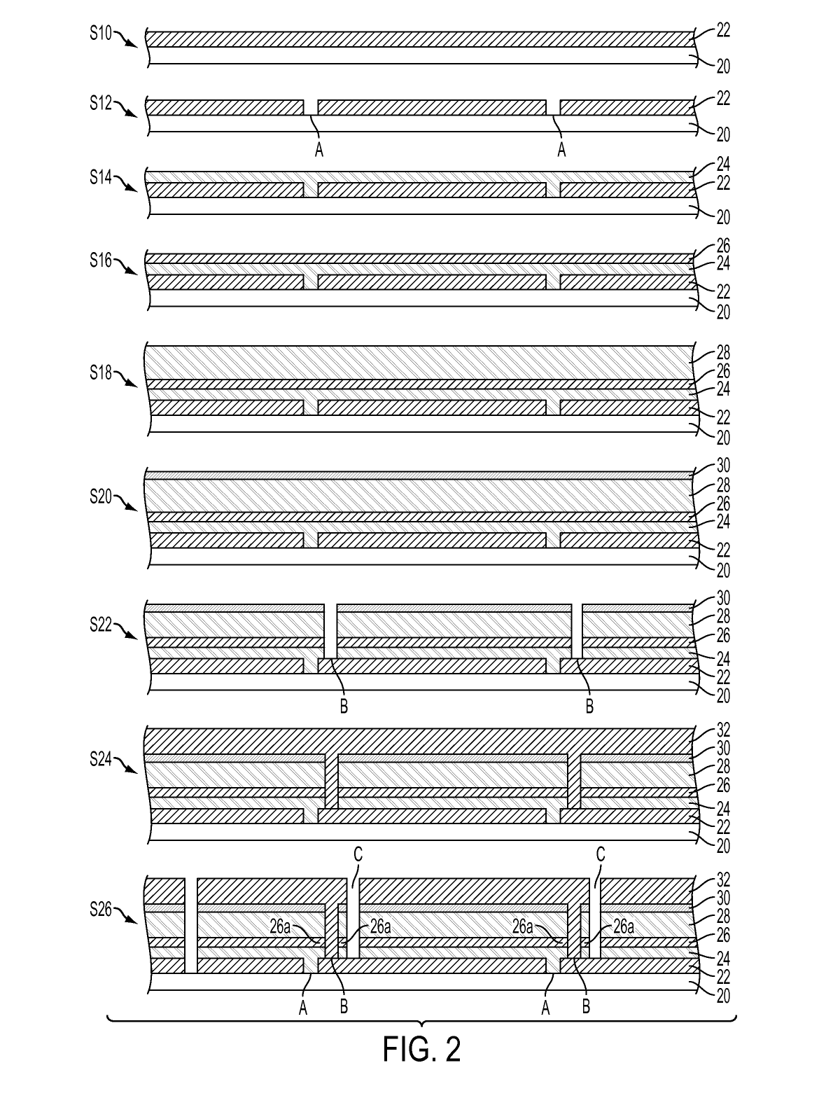

A method of manufacturing and a structure of the photovoltaic device 100 will now be described with reference to the manufacturing step diagram of FIG. 2. In order to clearly show the structure of the photovoltaic device, in FIGS. 1 and 2, a part of the photovoltaic device 100 is shown in an enlarged manner, and the ratios of the elements are changed from the actual ratios.

In step S10, the front-side electrode 22 is formed over the substrate 20. The substrate 20 is formed with a material having a light-transmitting characteristic. The substrate 20 may be, for example, a glass substrate, a plastic substrate, or the like. The front-side electrode 22 is formed with a transparent conductive film having a light-transmitting characteristic. The front-side electrode 22 may be formed with, for example, ZnO, SiO₂, SnO₂, TiO₂, In₂O₃, or the like. Alternatively, F, Sn, Al, Fe, Ga, Nb, or the like may be doped into these metal oxides. The front-side electrode 22 is formed through, for example, sputtering.

In step S12, a first separation groove A is formed through the front-side electrode 22. The separation groove A is formed, for example, through laser machining. The separation groove A may be formed, for example, using Nd:YAG laser having a wavelength of approximately 532 nm (second harmonic of YAG laser) and an energy density of 1×10⁵ W/cm². A line width of the separation groove A is preferably set to greater than or equal to 10 μm and less than or equal to 200 μm.

In step S14, the first solar battery unit 24 is formed over the front-side electrode 22. In the present embodiment, the first solar battery unit 24 is an amorphous silicon solar battery. The first solar battery unit 24 is formed by stacking amorphous silicon films in the order of p-type, i-type, and n-type amorphous silicon films from the side near the substrate 20. A thickness of the i layer of the first solar battery unit 24 is preferably set to greater than or equal to 100 nm and less than or equal to 500 nm. The first solar battery unit 24 is formed, for example, through plasma chemical vapor deposition (CVD). TABLE 1 shows film-formation conditions of the first solar battery unit 24.

In step S16, the intermediate layer 26 is formed over the first solar battery unit 24. The intermediate layer 26 is formed with a material having a light-transmitting characteristic. The intermediate layer 26 may be formed with, for example, ZnO, SiO₂, SnO₂, TiO₂, In₂O₃, or the like. Alternatively, F, Sn, Al, Fe, Ga, Nb, or the like may be doped into these metal oxides. A thickness of the intermediate layer 26 is preferably set to greater than or equal to 10 nm and less than or equal to 200 nm. The intermediate layer 26 is formed, for example, through RF sputtering. TABLE 1 shows film-formation conditions of the intermediate layer 26.

In step S18, the second solar battery unit 28 is formed over the intermediate layer 26. In the present embodiment, the second solar battery unit 28 is a microcrystalline silicon solar battery. The second solar battery unit 28 is formed by stacking microcrystalline silicon films in the order of p-type, i-type, and n-type microcrystalline silicon films from the side near the substrate 20. A thickness of the i layer of the second solar battery unit 28 is preferably greater than or equal to 1000 nm and less than or equal to 5000 nm. The second solar battery unit 28 is formed, for example, through plasma chemical vapor deposition (CVD). TABLE 1 shows film-formation conditions of the second solar battery unit 28.

TABLE 1

| | SUBSTRATE | GAS FLOW | REACTION | | FILM |
|---|---|---|---|---|---|
| | TEMPERATURE | RATE | PRESSURE | RF POWER | THICKNESS |
| | (° C.) | (sccm) | (Pa) | (W) | (nm) |
| P-LAYER | 180 | SiH₄: 300 | 106 | 10 | 15 |
| (AMORPHOUS | | CH₄: 300 | | | |
| SILLICON) | | H₂: 2000 | | | |
| | | B₂H₆: 3 | | | |
| I-LAYER | 200 | SiH₄: 300 | 106 | 20 | 200 |
| (AMORPHOUS | | H₂: 2000 | | | |
| SILLICON) | | | | | |
| N-LAYER | 180 | SiH₄: 300 | 133 | 20 | 30 |
| (AMORPHOUS | | H₂: 2000 | | | |
| SILLICON) | | PH₃: 5 | | | |
| INTERMEDIATE | 170 | Ar: 10 | 0.4 | 400 | 30 |
| LAYER (ZnO) | | | | | |
| P-LAYER | 180 | SiH₄: 10 | 106 | 10 | 30 |
| (MICROCRYSTALLINE | | H₂: 2000 | | | |
| SILLICON) | | B₂H₆: 3 | | | |
| I-LAYER | 200 | SiH₄: 100 | 133 | 20 | 2000 |
| (MICROCRYSTALLINE | | H₂: 2000 | | | |
| SILLICON) | | | | | |
| N-LAYER | 200 | SiH₄: 10 | 133 | 20 | 20 |
| (MICROCRYSTALLINE | | H₂: 2000 | | | |
| SILLICON) | | PH₃: 5 | | | |

In step S20, the backside electrode 30 is formed over the second solar battery unit 28. The backside electrode 30 preferably has a stacked structure of a transparent conductive film and a metal film. The transparent conductive film may be, for example, ZnO, SiO₂, SnO₂, TiO₂, In₂O₃, or the like, and is preferably ZnO. For the metal film, for example, silver (Ag), aluminum (Al), gold (Au), or the like may be used, and, in consideration of the reflectivity of light to be used, silver (Ag) is preferred. The backside electrode 30 is formed, for example, through sputtering.

In step S22, a second separation groove B is formed. The separation groove B is formed through the backside electrode 30, the second solar battery unit 28, the intermediate layer 26, and the first solar battery unit 24, to reach the front-side electrode 22. A line width of the separation groove B is preferably greater than or equal to 10 μm and less than or equal to 200 μm. The separation groove B is formed, for example, through lasermachining. For example, the separation groove B may be formed using Nd:YAG laser having a wavelength of approximately 532 nm (second harmonic of YAG laser) and an energy density of 1×10⁵ W/cm².

In step S24, the electrode connecting layer 32 is formed over the backside electrode 30. The electrode connecting layer 32 is formed in an embedded manner in the separation groove B, and the front-side electrode 22 and the backside electrode 30 are electrically connected by the electrode connecting layer 32. The electrode connecting layer 32 is formed, for example, through sputtering.

The electrode connecting layer 32 is partially connected to an end 26a of the intermediate layer 26 in the separation groove B. The electrode connecting layer 32 is formed with a material which forms a Schottky barrier Φ at the boundary with the end 26a of the intermediate layer 26. In other words, the combination of the materials of the electrode connecting layer 32 and the intermediate layer 26 is selected such that a work function Φm of the material of the electrode connecting layer 32 is greater than an electron affinity χ of the material of the intermediate layer 26.

By forming the Schottky barrier between the electrode connecting layer 32 and the intermediate layer 26, it is possible to reduce current leakage through the intermediate layer 26. In other words, because the electrode connecting layer 32 is a negative electrode, the electrode connecting layer 32 and the intermediate layer 26 are put in a reverse bias state, and the current flowing between the intermediate layer 26 and the electrode connecting layer 32 is significantly reduced. In this configuration, it is deduced that a voltage of approximately the open voltage of the second solar battery unit 28 is applied as the reverse bias.

A current I1 flowing from the electrode connecting layer 32 to the intermediate layer 26 is determined depending on the height Φ of the Schottky barrier, and is given by Equation (1). Height Φ of the Schottky barrier equals (work function Φm of the material of the electrode connecting layer 32)−(electron affinity χ of the material of the intermediate layer 26):

(Equation 1)

I1=AT²×exp[−Φ/kT] (1)

wherein A represents the Richardson constant, k represents the Boltzmann constant, and T represents absolute temperature.

Similarly, a current I2 flowing from the intermediate layer 26 to the electrode connecting layer 32 is given by Equation (2):

(Equation 2)

I2=AT²×exp[−(Φ+eV)/kT] (2)

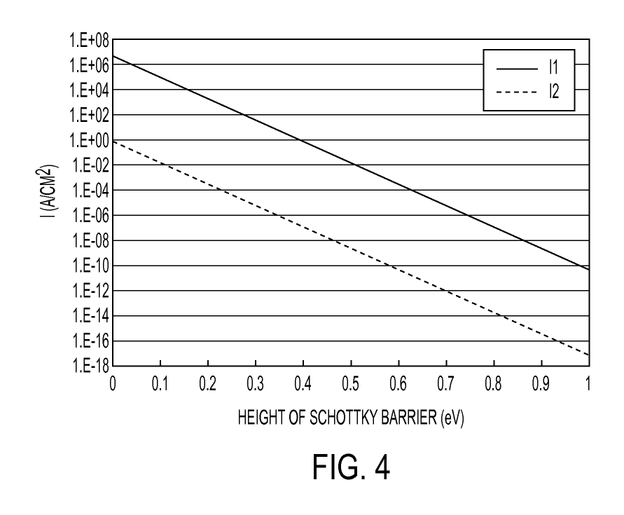

Here, when the intermediate layer 26 is ZnO, if an effective mass of the carrier (electron) of the intermediate layer 26 is 0.28 m₀ (wherein m₀ represents the effective mass of a free electron), the temperature T is 300 K, and a voltage V is the open voltage of the second solar battery unit 28 which is 0.4 V, the relationships between the height Φ of the Schottky barrier and the currents I1 and I2 are those shown in FIG. 4.

Specifically, by setting the Schottky barrier Φ between the electrode connecting layer 32 and the intermediate layer 26 to be greater than or equal to 0.75 eV, it is possible to limit the current I2 flowing from the electrode connecting layer 32 to the intermediate layer 26 to a value of less than or equal to 1 μA/cm².

As materials of the intermediate layer 26 and the electrode connecting layer 32 satisfying these conditions, when the intermediate layer 26 is ZnO, SnO₂, TiO₂, In₂O₃, or SiO₂, Ni (Φm=5.15 eV), Ir (Φm=5.27 eV), or Pt (Φm=5.65 eV) is preferably used for the electrode connecting layer 32.

If the current I2 flowing from the electrode connecting layer 32 to the intermediate layer 26 is to be inhibited to approximately 0.1 mA/cm², the material of the electrode connecting layer 32 should satisfy a condition of Schottky barrier Φ≧0.62 eV. More specifically, the material of the electrode connecting layer 32 may preferably be Be (Φm=4.98 eV), C (Φm=5.0 eV), Co (Φm=5.0 eV, Ge (Φm=5.0 eV), Rh (Φm=4.98 eV), Pd (Φm=5.12 eV), or Au (Φm=5.1 eV).

Alternatively, these materials may be stacked to form the electrode connecting layer 32, or these materials may be combined into an alloy to form the electrode connecting layer 32.

Similar to the present embodiment, when the intermediate layer 26 primarily comprises an n-type semiconductor, if the work function Φm of the material of the electrode connecting layer 32 is greater than the electron affinity χ of the material of the intermediate layer 26, a Schottky barrier is formed.

In step S26, a third separation groove C is formed. The separation groove C is formed through the electrode connecting layer 32, the backside electrode 30, the second solar battery unit 28, the intermediate layer 26, and the first solar battery unit 24, and reaching the front-side electrode 22. The separation groove C is formed at a position where the separation groove B is positioned between the separation groove C and the separation groove A. The separation groove C may be formed through laser machining. For example, the separation groove C may be formed using a Nd:YAG laser having a wavelength of approximately 532 nm (second harmonic of YAG laser) and an energy density of 1×10⁵ W/cm².

TABLE 2 shows a characteristic of the photovoltaic device 100 manufactured in the present embodiment. In this description, the open voltage Voc at a low luminance (10000 lux) which can be used as a criterion of current leakage is compared with the characteristic of the photovoltaic device of related art. In the manufacturing method of the photovoltaic device of related art, a separation groove is formed through the second solar battery unit 28, the intermediate layer 26, and the first solar battery unit 24, and reaching the front-side electrode 22 before the backside electrode 30 is formed, and then, the backside electrode is formed in an embedded manner in the separation groove, and the separation groove for separating the cells is formed. In the related art, the backside electrode has the roles of the backside electrode 30 and the electrode connecting layer 32 of the present embodiment.

In the photovoltaic device 100 of the present embodiment, ZnO is used as the intermediate layer 26, a stacked electrode of a ZnO film (with a thickness of 90 nm) and a Ag film (with a thickness of 200 nm) is used as the backside electrode 30, and a Ni film (with a thickness of 100 nm) is used as the electrode connecting layer 32. For the photovoltaic device of the related art, the electrode connecting layer 32 is not provided, and the same materials as those in the photovoltaic device 100 of the present invention are used as the materials of the intermediate layer 26 and the backside electrode 30.

TABLE 2

| | OPEN |
|---|---|
| | VOLTAGE |
| | Voc |
| THE PRESENT, | 1.04 |
| EMBODIMENT | |
| COMPARATIVE EXAMPLE | 1 |

In the photovoltaic device 100 of the present embodiment, the open voltage Voc at a low illuminance is improved by approximately 4% compared to the related art. This can be considered as due to the reduction in the current leakage between the intermediate layer 26 and the electrode connecting layer 32.

The present embodiment has been described exemplifying a tandem-structured thin film solar battery having a structure of amorphous silicon/microcrystalline silicon. The present invention, however, is not limited to such a configuration. That is, similar advantages can be obtained for any photovoltaic device which uses a transparent conductive film as an intermediate layer. In particular, similar advantages can be obtained by any silicon solar battery in which silicon is used as the primary material, and the intermediate layer formed of the transparent conductive film is provided in a region adjacent to silicon.

When the intermediate layer primarily comprises a p-type semiconductor also, similar advantages can be obtained by forming the Schottky barrier between the intermediate layer and the electrode connecting layer. In this case, when the work function Φm of the material of the electrode connecting layer is lower than the work function Φs of the material of the intermediate layer, the Schottky barrier is formed.

Alternatively, post-processing such as annealing, dry etching, ozone wash may be executed after the separation groove B is formed, and the electrode connecting layer may be formed. With the laser machining, scattered materials, fused materials, or the like may be adhered to the side surface of the separation groove B. The post processing is executed to prevent the phenomenon that superior a Schottky junction is not formed between the intermediate layer and the electrode connecting layer when the electrode connecting layer is formed in a state where such adhered materials exist.

What is claimed is:

1. A photovoltaic device in which a first solar battery unit and a second solar battery unit are stacked between a first electrode and a second electrode and sandwich an intermediate layer having conductivity, wherein
a Schottky barrier is formed between the intermediate layer and a material which connects the first electrode and the second electrode.

2. The photovoltaic device according to claim 1, wherein
the Schottky barrier is greater than or equal to 0.62 eV.

3. The photovoltaic device according to claim 1, wherein
the material includes at least one of Ni, Ir, Pt, Be, C, Co, Ge, Rh, Pd, and Au.

4. The photovoltaic device according to claim 2, wherein
the material includes at least one of Ni, Ir, Pt, Be, C, Co, Ge, Rh, Pd, and Au.

5. The photovoltaic device according to claim 1, wherein
the intermediate layer includes at least one of ZnO, SnO₂, TiO₂, In₂O₂, and SiO₂.

6. The photovoltaic device according to claim 2, wherein
the intermediate layer includes at least one of ZnO, SnO₂, TiO₂, In₂O₂, and SiO₂.

7. The photovoltaic device according to claim 3, wherein
the intermediate layer includes at least one of ZnO, SnO₂, TiO₂, In₂O₂, and SiO₂.

8. A method of manufacturing a photovoltaic device in which a first solar battery unit and a second solar battery unit are stacked between a first electrode and a second electrode and sandwich an intermediate layer having conductivity, the method comprising:
a first step in which a groove is formed through the first solar battery unit, the second solar battery unit, and the intermediate layer and reaching a front surface of the first electrode; and
a second step in which a material which connects the first electrode and the second electrode through the groove, and which forms a Schottky barrier with the intermediate layer, is embedded.

9. The method of manufacturing a photovoltaic device according to claim 8, wherein
the Schottky barrier is greater than or equal to 0.62 eV.

10. The method of manufacturing a photovoltaic device according to claim 8, wherein
the material includes at least one of Ni, Ir, Pt, Be, C, Co, Ge, Rh, Pd, and Au.

11. The method of manufacturing a photovoltaic device according to claim 9, wherein
the material includes at least one of Ni, Ir, Pt, Be, C, Co, Ge, Rh, Pd, and Au.

12. The method of manufacturing a photovoltaic device according to claim 8, wherein
the intermediate layer includes at least one of ZnO, SnO₂, TiO₂, In₂O₃, and SiO₂.

13. The method of manufacturing a photovoltaic device according to claim 9, wherein
the intermediate layer includes at least one of ZnO, SnO₂, TiO₂, In₂O₃, and SiO₂.

14. The method of manufacturing a photovoltaic device according to claim 10, wherein
the intermediate layer includes at least one of ZnO, SnO₂, TiO₂, In₂O₃, and SiO₂.
